(19) United States
(12) Patent Application Publication
(10) Pub. No.: US 2011/0132425 A1
(43) Pub. Date: Jun. 9, 2011

(54) SOLAR CELL MODULE

(76) Inventors: Juwan Kang, Seoul (KR); Jiweon Jeong, Seoul (KR); Jonghwan Kim, Seoul (KR)

(21) Appl. No.: 12/846,614

(22) Filed: Jul. 29, 2010

(30) Foreign Application Priority Data
Dec. 9, 2009 (KR) 10-2009-0121772

(51) Int. Cl. H01L 31/05

(52) U.S. Cl. 136/244

(57) ABSTRACT

A solar cell module is disclosed. The solar cell module includes at least one first solar cell, the at least one first solar cell including a first semiconductor substrate of a first conductive type, and a first electron current collector and a first hole current collector that are positioned on one surface of the first semiconductor substrate; and at least one second solar cell, the at least one second solar cell including a second semiconductor substrate of a second conductive type opposite the first conductive type, and a second electron current collector and a second hole current collector that are positioned on one surface of the second semiconductor substrate. The first solar cell and the second solar cell are positioned adjacently to each other and are alternately positioned.

This application claims priority to and the benefit of Korean Patent Application No. 10-2009-0121772 filed in the Korean Intellectual Property Office on Dec. 9, 2009, the entire contents of which is incorporated herein by reference.

### BACKGROUND OF THE INVENTION

1. Field of the Invention

Embodiments of the invention relate to a solar cell module including a plurality of solar cells.

2. Description of the Related Art

Recently, as existing energy sources such as petroleum and coal are expected to be depleted, interests in alternative energy sources for replacing the existing energy sources are increasing. Among the alternative energy sources, solar cells generating electric energy from solar energy have been particularly spotlighted.

A solar cell generally includes a p-type semiconductor substrate, an n-type emitter layer on one surface, for example, a light receiving surface of the p-type semiconductor substrate, and a first electrode and a second electrode respectively formed on the substrate and the emitter layer. In other words, the first and second electrodes are respectively formed on the different semiconductors. At least one current collector such as a bus bar is formed in each of the first and second electrodes.

When light is incident on the solar cell, electrons inside the semiconductors become free electrons (hereinafter referred to as “electrons”) by the photoelectric effect. Further, electrons and holes respectively move to the n-type semiconductor (e.g., the emitter layer) and the p-type semiconductor (e.g., the substrate) in accordance with the principle of p-n junction. The holes moving to the substrate and the electrons moving to the emitter layer are respectively collected by the first electrode and the second electrode respectively connected to the substrate and the emitter layer. Then, the holes and the electrons move to the respective current collectors connected to the first and second electrodes.

Because a very small amount of voltage and current are generated from one solar cell having the above-described structure, a solar cell module fabricated by connecting solar cells each having the above-described structure in series or in parallel to one another is used to obtain a desired output. The solar cell module is a moisture-proof module fabricated in a panel form.

In the solar cell module, the electrons and the holes collected by the current collectors of each solar cell are collected by a junction box formed on a back surface of the solar cell module, and an interconnector, for example, a ribbon is used to connect the solar cells to one another.

In the related art solar cell module, all of the solar cells each include the semiconductor substrate of the same conductive type. Thus, when the adjacent solar cells are electrically connected to one another using the interconnector, one terminal of the interconnector is connected to the first electrode positioned on a light receiving surface of one solar cell, and the other terminal of the interconnector is connected to the second electrode positioned on a surface opposite a light receiving surface of another solar cell adjacent to the one solar cell.

Because of these reasons, a manual work is required to electrically connect the related art solar cells to one another using the interconnector. Accordingly, yield in a module process of the related art solar cell module is reduced, and work time increases.

Further, in the related art solar cell module, because a portion of the interconnector for electrically connecting the two adjacent solar cells to each other is positioned in a space between the two adjacent solar cells, the space for the interconnector has to be secured between the solar cells. A magnitude of the space, i.e., a distance between the solar cells is constant, for example, about 3 mm or more. Accordingly, there is a limit to a reduction in the size of the solar cell module.

### SUMMARY OF THE INVENTION

In one aspect, there is a solar cell module including at least one first solar cell, the at least one first solar cell including a first semiconductor substrate of a first conductive type, and a first electron current collector and a first hole current collector that are positioned on one surface of the first semiconductor substrate; and at least one second solar cell, the at least one second solar cell including a second semiconductor substrate of a second conductive type opposite the first conductive type, and a second electron current collector and a second hole current collector that are positioned on one surface of the second semiconductor substrate.

Accordingly, a yield in a module process of the solar cells can be improved, and work time required in the electrical connection using the interconnector can be reduced.

Because a space for a portion of the interconnector is removed, a space between the solar cells can be reduced. For example, a distance between the solar cells may be approximately equal to or less than 1 mm. Accordingly, a dead space of the solar cell module can be reduced, and the size of the solar cell module can be reduced.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is an exploded perspective view of a solar cell module according to an embodiment of the invention;

FIG. 2 is a partial cross-sectional view of a first solar cell according to an embodiment of the invention;

FIG. 3 is a partial cross-sectional view of a second solar cell according to an embodiment of the invention;

FIG. 4 is a lateral view illustrating an arrangement structure and an electrical connection structure of first and second solar cells according to an embodiment of the invention;

FIG. 5 is a partial perspective view of a first solar cell according to another embodiment of the invention;

FIG. 6 is a partial perspective view of a second solar cell according to another embodiment of the invention; and

FIG. 7 is a bottom plane view illustrating an arrangement structure and an electrical connection structure of first and second solar cells according to another embodiment of the invention.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

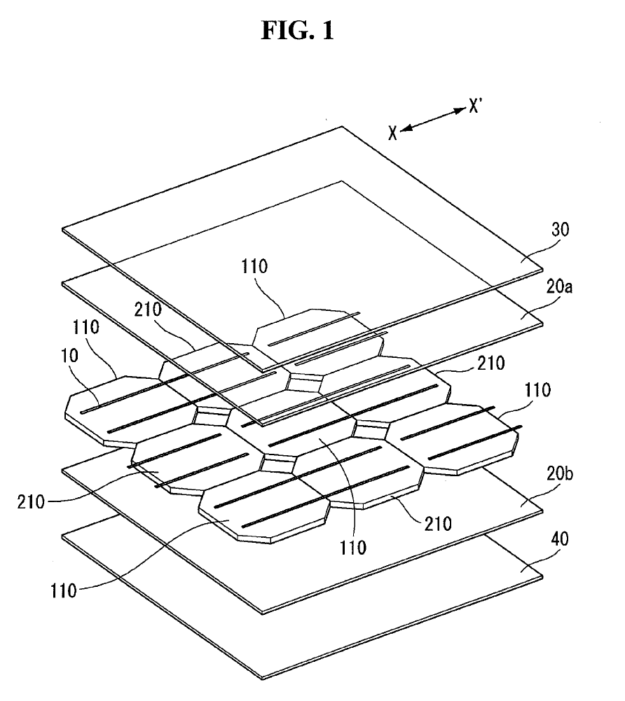

FIG. 1 is an exploded perspective view of a solar cell module according to an embodiment of the invention.

As shown in FIG. 1, a solar cell module according to an embodiment of the invention includes a plurality of solar cells 110 and 210, an interconnector 10 for electrically connecting the plurality of solar cells 110 and 210 to one another, upper and lower protective layers 20a and 20b for protecting the solar cells 110 and 210, a transparent member 30 on the upper protective layer 20a that is positioned near to light receiving surfaces of the solar cells 110 and 210, a back sheet 40 underlying the lower protective layer 20b that is positioned near to surfaces opposite the light receiving surfaces of the solar cells 110 and 210, and a frame receiving the components 110, 210, 10, 20a, 20b, 30, and 40 that form an integral body through a lamination process.

The back sheet 40 prevents moisture or oxygen from penetrating into a back surface of the solar cell module, thereby protecting the solar cells 110 and 210 from an external environment. The back sheet 40 may have a multi-layered structure including a moisture/oxygen penetrating prevention layer, a chemical corrosion prevention layer, a layer having insulating characteristics, etc.

The upper and lower protective layers 20a and 20b and the solar cells 110 and 210 form an integral body when a lamination process is performed in a state where the upper and lower protective layers 20a and 20b are respectively positioned on and under the solar cells 110 and 210. The upper and lower protective layers 20a and 20b prevent corrosion of metal resulting from the moisture penetration and protect the solar cells 110 and 210 from an impact. The upper and lower protective layers 20a and 20b may be formed of ethylene vinyl acetate (EVA). Other materials may be used.

The transparent member 30 on the upper protective layer 20a is formed of a tempered glass having a high light transmittance and excellent damage prevention characteristic. The tempered glass may be a low iron tempered glass containing a small amount of iron. The transparent member 30 may have an embossed inner surface so as to increase a scattering effect of light.

A method of fabricating the solar cell module sequentially includes testing the solar cells 110 and 210, electrically connecting the tested solar cells 110 and 210 to one another using the interconnector 10, sequentially disposing the components 110, 210, 20a, 20b, 30, and 40, for example, sequentially disposing the back sheet 40, the lower protective layer 20b, the solar cells 110 and 210, the upper protective layer 20a, and the transparent member 30 from the bottom of the solar cell module in the order named, performing the lamination process in a vacuum state to form an integral body of the components 110, 210, 20a, 20b, 30, and 40, performing an edge trimming process, testing the solar cell module, and the like.

In the embodiment of the invention, the plurality of solar cells 110 and 210 disposed between the upper protective layer 20a and the lower protective layer 20b include at least one first solar cell 110 and at least one second solar cell 210.

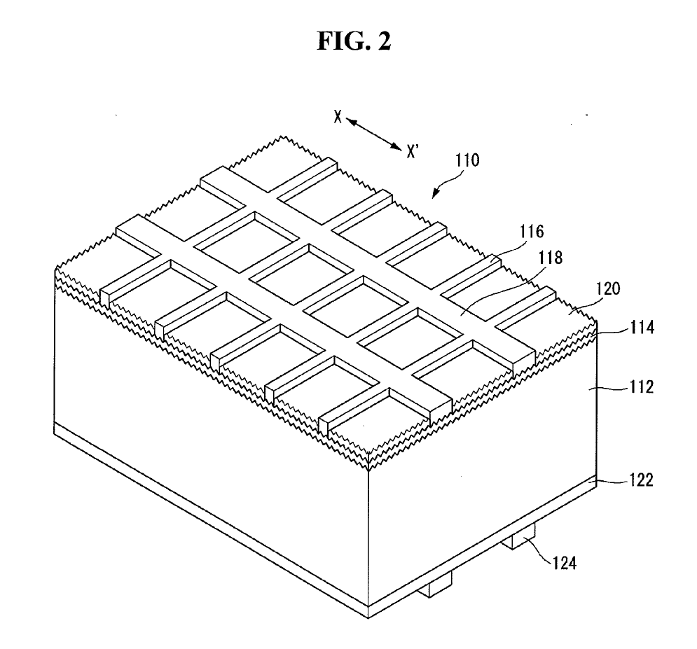

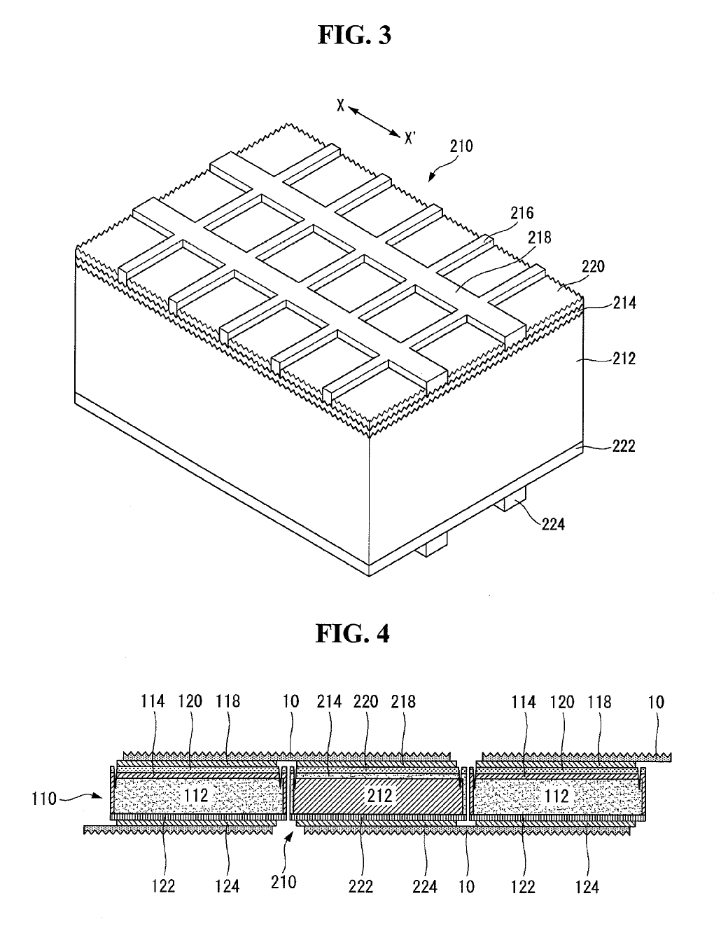

FIG. 2 is a partial cross-sectional view of the first solar cell 110, and FIG. 3 is a partial cross-sectional view of the second solar cell 210.

As shown in FIG. 2, the first solar cell 110 includes a first semiconductor substrate 112 formed of first conductive type silicon, for example, p-type silicon, though not required. Silicon used in the first semiconductor substrate 112 may be single crystal silicon, polycrystalline silicon, or amorphous silicon. When the first semiconductor substrate 112 is of a p-type, the first semiconductor substrate 112 contains impurities of a group III element such as boron (B), gallium (Ga), and indium (In).

The surface of the first semiconductor substrate 112 may be textured to form a textured surface corresponding to an uneven surface or having uneven characteristics.

When the surface of the first semiconductor substrate 112 is the textured surface, a light reflectance in a light receiving surface of the first semiconductor substrate 112 is reduced. Further, because both a light incident operation and a light reflection operation are performed on the textured surface of the first semiconductor substrate 112, light is confined in the first solar cell 110. Hence, a light absorption increases, and efficiency of the first solar cell 110 is improved. In addition, because a reflection loss of light incident on the first semiconductor substrate 112 decreases, an amount of light incident on the first semiconductor substrate 112 further increases.

An emitter layer 114 is positioned in the light receiving surface of the first semiconductor substrate 112. The emitter layer 114 is an impurity region doped with impurities of a second conductive type (for example, an n-type) opposite the first conductive type of the first semiconductor substrate 112. The emitter layer 114 forms a p-n junction along with the first semiconductor substrate 112. When the emitter layer 114 is of the n-type, the emitter layer 114 may be formed by doping the first semiconductor substrate 112 with impurities of a group V element such as phosphor (P), arsenic (As), and antimony (Sb).

When energy produced by light incident on the first semiconductor substrate 112 is applied to carriers inside the semiconductors, electrons move to the n-type semiconductor and holes move to the p-type semiconductor. Thus, when the first semiconductor substrate 112 is of the p-type and the emitter layer 114 is of the n-type, the holes move to the p-type substrate 112 and the electrons move to the n-type emitter layer 114.

A plurality of first electron electrodes 116 are positioned on the emitter layer 114 to be spaced apart from one another. The first electron electrodes 116 are electrically connected to the emitter layer 114 and extend in one direction. Each of the first electron electrodes 116 collects carriers (e.g., electrons) moving to the emitter layer 114. The first electron electrodes 116 are formed of at least one conductive material. The conductive material may be at least one selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used for the first electron electrodes 116.

At least one first electron current collector 118 is positioned on the emitter layer 114. The first electron current collector 118 called a bus bar is formed in a direction crossing the first electron electrodes 116. Thus, the first electron electrodes 116 and the first electron current collector 118 are positioned on the emitter layer 114 in a crossing structure.

The first electron current collector 118 is electrically connected to the emitter layer 114 and the first electron electrodes 116. Thus, the first electron current collector 118 outputs the carriers (e.g., electrons) transferred from the first electron electrodes 116 to an external device.

The first electron current collector 118 is formed of at least one conductive material. The conductive material may be at least one selected from the group consisting of Ni, Cu, Ag, Al, Sn, Zn, In, Ti, Au, and a combination thereof. Other conductive materials may be used for the first electron current collector 118.

In the embodiment of the invention, the first electron current collector 118 may contain the same material as or a different material than the first electron electrodes 116.

The first electron electrodes 116 and the first electron current collector 118 may be electrically connected to the emitter layer 114 in a process in which the conductive material is coated on an anti-reflection layer 120, is patterned in a pattern form shown in FIG. 2, and is fired.

The anti-reflection layer 120 is formed on the emitter layer 114 on which the first electron electrodes 116 and the first electron current collector 118 are not formed. The anti-reflection layer 120 is formed of silicon nitride (SiNx) and/or silicon dioxide (SiO₂). Other conductive materials may be used. The anti-reflection layer 120 reduces a reflectance of light incident on the first solar cell 110 and increases a selectivity of a predetermined wavelength band, thereby increasing the efficiency of the first solar cell 110. The anti-reflection layer 120 may have a thickness of about 70 nm to 80 nm. The anti-reflection layer 120 may be omitted, if desired.

A first hole electrode 122 is positioned on a surface (i.e., a back surface of the first semiconductor substrate 112) opposite the light receiving surface of the first semiconductor substrate 112. The first hole electrode 122 collects carriers (e.g., holes) moving to the first semiconductor substrate 112. The first hole electrode 122 is formed of at least one conductive material. The conductive material may be at least one selected from the group consisting of Ni, Cu, Ag, Al, Sn, Zn, In, Ti, Au, and a combination thereof. Other conductive materials may be used for the first hole electrode 122.

A first hole current collector 124 is positioned under the first hole electrode 122. The first hole current collector 124 is formed in a direction crossing the first electron electrodes 116, i.e., in a direction parallel to the first electron current collector 118.

The first hole current collector 124 is electrically connected to the first hole electrode 122. Thus, the first hole current collector 124 outputs the carriers (e.g., holes) transferred from the first hole electrode 122 to the external device.

The first hole current collector 124 is formed of at least one conductive material. The conductive material may be at least one selected from the group consisting of Ni, Cu, Ag, Al, Sn, Zn, In, Ti, Au, and a combination thereof. Other conductive materials may be used for the first hole current collector 124.

The first solar cell 110 may further include a back surface field (BSF) layer between the first hole electrode 122 and the first semiconductor substrate 112. The back surface field layer is a region (e.g., a p⁺-type region) that is more heavily doped with impurities of the same conductive type as the first semiconductor substrate 112 than the first semiconductor substrate 112. The back surface field layer serves as a potential barrier of the first semiconductor substrate 112. Thus, because a recombination and/or a disappearance of electrons and holes around the back surface of the first semiconductor substrate 112 are prevented or reduced, the efficiency of the first solar cell 110 is improved.

So far, the configuration of the first solar cell 110 is described in detail. Configuration of the second solar cell 210 is substantially the same as the first solar cell 110, except that conductive types of the corresponding components of the first and second solar cells 110 and 210 are opposite to each other. Thus, the configuration of the second solar cell 210 may be briefly described with reference to FIG. 3.

As shown in FIG. 3, a second semiconductor substrate 212 of the second solar cell 210 is formed of second conductive type silicon, for example, n-type silicon, though not required. When the second semiconductor substrate 212 is of the n-type, the second semiconductor substrate 212 may contain impurities of a group V element such as phosphor (P), arsenic (As), and antimony (Sb).

Because an emitter layer 214 forms a p-n junction along with the second semiconductor substrate 212, the emitter layer 214 is of the first conductive type (e.g., p-type). Thus, when the emitter layer 214 is of the p-type, the emitter layer 214 may be formed by doping the second semiconductor substrate 212 with impurities of a group III element such as boron (B), gallium (Ga), and indium (In).

In the second solar cell 210 having the above-described structure, electrons move to the second semiconductor substrate 212, and holes move to the emitter layer 214.

A plurality of second hole electrodes 216 and at least one second hole current collector 218 are positioned on the emitter layer 214, and a second electron electrode 222 and a second electron current collector 224 are positioned on a back surface of the second semiconductor substrate 212.

The second solar cell 210 includes an anti-reflection layer 220. The second solar cell 210 may have a textured surface of the second semiconductor substrate 212 in the same manner as the first solar cell 110 and may further include a back surface field layer.

The second hole electrodes 216, the second hole current collector 218, the second electron electrode 222, and the second electron current collector 224 may be formed of at least one conductive material selected from the group consisting of Ni, Cu, Ag, Al, Sn, Zn, In, Ti, Au, and a combination thereof. Other conductive materials may be used.

FIGS. 2 and 3 illustrate that the first hole current collector 124 is positioned on the first hole electrode 122 and the second electron current collector 224 is positioned on the second electron electrodes 222. However, the first hole electrode 122 and the first hole current collector 124 may be positioned on the same plane (or the same plane level or may be coplanar), and the second electron electrodes 222 and the second electron current collector 224 may be positioned on the same plane (or the same plane level or may be coplanar).

In other words, the first hole current collector 124 may be positioned on the back surface of the first semiconductor substrate 112 on which the first hole electrode 122 is not formed, and the second electron current collector 224 may be positioned on the back surface of the second semiconductor substrate 212 on which the second electron electrodes 222 is not formed. In this case, the first hole electrode 122 and the first hole current collector 124 are formed in the same direction, and the second electron electrodes 222 and the second electron current collector 224 are formed in the same direction.

As shown in FIGS. 2 and 3, a structure of the first solar cell 110 and a structure of the second solar cell 210 have at least one difference. One difference between the structure of the first solar cell 110 and structure of the second solar cell 210 is the different conductivity type of the respective semiconductor substrates.

In embodiments of the invention, the at least one difference in the structure of the first solar cell 110 and the structure of second solar cell 210 includes reference to having semiconductor substrates that are differently doped, such as different doping elements and/or different doping concentrations; that are differently processed; and/or having different surface characteristics, such as texturing or lack thereof. Further, the at least one difference also includes reference to having semiconductor substrates with different crystallinity of silicon, such as single crystal silicon, polycrystalline silicon, or amorphous silicon.

Additionally, the at least one difference also includes reference to having emitter layers of different doped species and/or concentrations; electron electrodes of different shapes, characteristics and/or materials; electron current collectors of different shapes, characteristics and/or materials; having or not having anti-reflection layers or a having anti-reflection layers of different shapes, characteristics, materials, layers and/or thicknesses; hole electrodes of different shapes, characteristics and/or materials; hole current collectors of different shapes, characteristics and/or materials; back surface fields of different shapes, characteristics and/or materials; interconnectors of different shape, characteristics and/or materials, and/or arrangements thereof; as well as other differences.

FIG. 4 is a lateral view illustrating an arrangement structure and an electrical connection structure of the first and second solar cells.

The first solar cells 110 and the second solar cells 210 are arranged in a matrix structure as shown in FIG. 1. Although FIG. 1 illustrates the first and second solar cells 110 and 210 having the structure of 3×3 matrix, the number of first and second solar cells 110 and 210 in row and column directions may vary, if necessary.

In the embodiment of the invention, at least one first solar cell 110 and at least one second solar cell 210 are arranged adjacently to each other. Preferably, though nut necessarily, the first solar cells 110 and the second solar cells 210 may be alternately arranged.

Further, the first solar cell 110 is configured so that the first electron electrodes 116 and the first electron current collector 118 are positioned toward a light source, and the second solar cell 210 is configured so that the second hole electrodes 216 and the second hole current collector 218 are positioned toward the light source. Accordingly, the first electron current collector 118 of the first solar cell 110 and the second hole current collector 218 of the second solar cell 210 are positioned on the same plane (or the same plane level or may be coplanar), and the first hole current collector 124 of the first solar cell 110 and the second electron current collector 224 of the second solar cell 210 are positioned on the same plane (or the same plane level or may be coplanar).

When the first solar cells 110 and the second solar cells 210 are arranged in the matrix structure, each first solar cell 110 and each second solar cells 210 are arranged so that a longitudinal direction X-X′ of the first electron current collector 118 is equal to a longitudinal direction X-X′ of the second hole current collector 218, and at the same time, a longitudinal direction X-X′ of the first hole current collector 124 is equal to a longitudinal direction X-X′ of the second electron current collectors 224. Hence, one end of the first electron current collector 118 is opposite to one end of the second hole current collector 218, and one end of the first hole current collector 124 is opposite to one end of the second electron current collector 224.

Accordingly, in the solar cell module having the above-described matrix structure, as shown in FIG. 4, the interconnector 10 for electrically connecting the first electron current collector 118 of the first solar cell 110 to the second hole current collector 218 of the second solar cell 210 may be straightly positioned on the same plane (or the same plane level). The interconnector 10 for electrically connecting the second electron current collector 224 of the second solar cell 210 to the first hole current collector 124 of the first solar cell 110 may be straightly positioned on the same plane (or the same plane level).

In other words, in the solar cell module according to the embodiment of the invention, the first electron current collector 118 of the first solar cell 110 and the second hole current collector 218 of the second solar cell 210 are positioned on the same plane (or the same plane level or may be coplanar), and the first hole current collector 124 of the first solar cell 110 and the second electron current collector 224 of the second solar cell 210 are positioned on the same plane (or the same plane level or may be coplanar). Therefore, the electrical connection between the solar cells 110 and 210 using the interconnector 10 can be easily performed. Further, a yield in a module process of the solar cells 110 and 210 can be improved, and a distance between the solar cells 110 and 210 may be reduced to be equal to or less than about 1 mm.

In FIG. 4, the interconnector 10, the first electron current collector 118 of the first solar cell 110, and the second hole current collector 218 of the second solar cell 210 are connected in a straight line. In other words, the interconnector 10, the first electron current collector 118, and the second hole current collector 218 are collinear.

The interconnector 10 may have a textured surface in the same manner as the first and second semiconductor substrates 112 and 212. When the interconnector 10 is positioned on the light receiving surfaces of the solar cells 110 and 210 as shown in FIG. 4, the textured surface of the interconnector 10 positioned near to the light receiving surfaces of the substrates 112 and 212 may be a surface opposite a surface of the interconnector 10 contacting the light receiving surfaces of the solar cells 110 and 210. When the interconnector 10 is positioned on the back surfaces of the substrates 112 and 212 as shown in FIG. 4, the textured surface of the interconnector 10 may be a surface opposite a surface of the interconnector 10 contacting the back surfaces of the substrates 112 and 212. The interconnector 10 having the above-described configuration can efficiently increase an absorptance of light while preventing a reduction in an adhesive strength between the interconnector 10 and the corresponding current collectors of the solar cells 110 and 210.

Although the first solar cells 110 and the second solar cells 210 are alternately arranged in the embodiment of the invention described above by way of example, other arrangements may be used. For example, first groups each including the two or three first solar cells 110 and second groups each including the two or three second solar cells 210 may be alternately arranged.

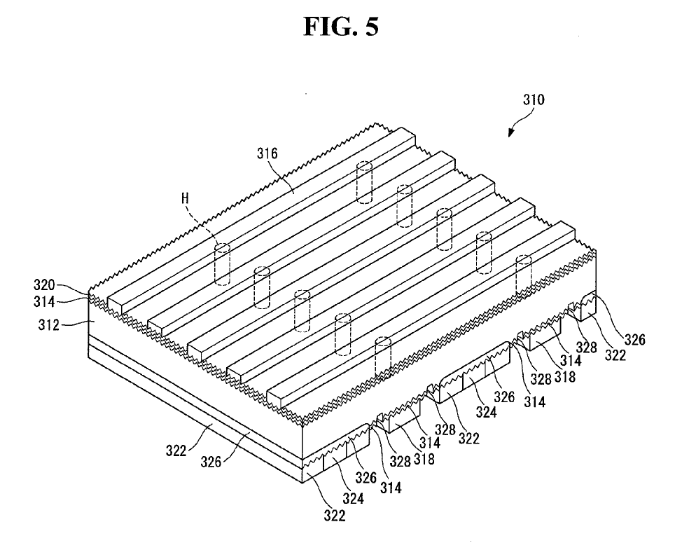

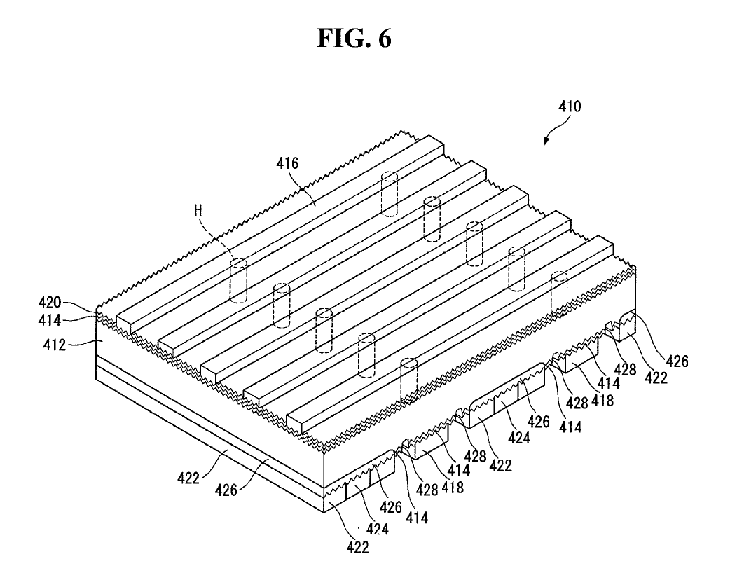

FIGS. 5 and 6 are partial perspective views of a first solar cell and a second solar cell according to another embodiment of the invention.

As shown in FIG. 5, a first solar cell 310 includes a first semiconductor substrate 312 of a first conductive type (for example, a p-type) having a plurality of via holes H, an emitter layer 314 positioned in an entire surface of the first semiconductor substrate 312, a plurality of first electron electrodes 316 positioned on the emitter layer 314 of a front surface corresponding to a light receiving surface of the first semiconductor substrate 312, a plurality of first electron current collectors 318 that are positioned on the emitter layer 314 of a back surface opposite the front surface of the first semiconductor substrate 312 in and around the via holes H and are electrically connected to the plurality of first electron electrodes 316, an anti-reflection layer 320 positioned on the emitter layer 314 of the front surface of the first semiconductor substrate 312 on which the first electron electrodes 316 are not positioned, a plurality of first hole electrodes 322 positioned on the back surface of the first semiconductor substrate 312, a plurality of first hole current collectors 324 that are positioned on the back surface of the first semiconductor substrate 312 and are electrically connected to the first hole electrodes 322, and a plurality of back surface field layers 326 positioned between the first hole electrodes 322 and the first semiconductor substrate 312.

When the first semiconductor substrate 312 is of the p-type, the emitter layer 314 may contain second conductive type impurities (for example, n-type impurities). The surface of the first semiconductor substrate 312 may be textured to form a textured surface.

The first electron electrodes 316 are electrically and physically connected to the emitter layer 314. The first electron electrodes 316 collect carriers (e.g., electrons) moving to the emitter layer 314 and transfer the carriers to the first electron current collectors 318 electrically connected to the first electron electrodes 316 through the via holes H.

The first electron current collectors 318 on the back surface of the first semiconductor substrate 312 extend substantially parallel to one another in a direction crossing the first electron electrodes 316 positioned on the front surface of the first semiconductor substrate 312.

The via holes H in the first semiconductor substrate 312 are formed at crossings of the first electron electrodes 316 and the first electron current collectors 318. At least one of each first electron electrode 316 and each first electron current collector 318 extends to at least one of the front surface and the back surface of the first semiconductor substrate 312 through the via holes H. Thus, the first electron electrodes 316 and the first electron current collectors 318 respectively positioned on opposite surfaces of the first semiconductor substrate 312 are electrically connected to one another.

The first electron current collectors 318 output the carriers (e.g., electrons) transferred from the first electron electrodes 316 to an external device.

The first hole electrodes 322 on the back surface of the first semiconductor substrate 312 are positioned to be spaced apart from the first electron current collectors 318 adjacent to the first hole electrodes 322.

The first hole electrodes 322 are positioned on almost the entire back surface of the first semiconductor substrate 312 excluding a formation area of the first electron current collectors 318 from the back surface of the first semiconductor substrate 312. The first hole electrodes 322 collect carriers (e.g., holes) moving to the first semiconductor substrate 312.

The emitter layer 312 in the back surface of the first semiconductor substrate 312 has a plurality of exposing portions 328 that expose a portion of the back surface of the first semiconductor substrate 312 and surround the first electron current collectors 318. Thus, because the electrical connection between the first electron current collectors 318 for electron collection and the first hole electrodes 322 for hole collection is blocked by the exposing portions 328, the electrons and the holes move smoothly.

The first hole current collectors 324 are positioned on the back surface of the first semiconductor substrate 312 and are electrically and physically connected to the first hole electrodes 322. Further, the first hole current collectors 324 extend substantially parallel to the first electron current collectors 318. Thus, the first hole current collectors 324 collect carriers (e.g., holes) transferred from the first hole electrodes 322 and output the carriers to the external device.

Each of the back surface field layers 326 between the first hole electrodes 322 and the first semiconductor substrate 312 is a region (e.g., a p⁺-type region) that is more heavily doped with impurities of the same conductive type as the first semiconductor substrate 312 than the first semiconductor substrate 312.

So far, the configuration of the first solar cell 310 is described in detail with reference to FIG. 5. Configuration of a second solar cell 410 is substantially the same as the first solar cell 310, except that conductive types of the corresponding components of the first and second solar cells 310 and 410 are opposite to each other. Thus, the configuration of the second solar cell 410 may be briefly described with reference to FIG. 6.

A second semiconductor substrate 412 of the second solar cell 410 is of a second conductive type (for example, an n-type) and has a plurality of via holes H.

Because an emitter layer 414 forms a p-n junction along with the second semiconductor substrate 412, the emitter layer 414 is of a first conductive type (e.g., a p-type). Thus, when the emitter layer 414 is of the p-type, the emitter layer 414 may be formed by doping the second semiconductor substrate 412 with impurities of a group III element such as boron (B), gallium (Ga), and indium (In).

In the second solar cell 410 having the above-described structure, electrons move to the second semiconductor substrate 412, and holes move to the emitter layer 414.

An anti-reflection layer 420 and a plurality of second hole electrodes 416 are positioned on the emitter layer 414. A plurality of second hole current collectors 418, a plurality of second electron electrodes 422, and a plurality of second electron current collectors 424 electrically connected to the second electron electrodes 422 are positioned on a surface (i.e., a back surface) opposite a light receiving surface of the second semiconductor substrate 412. The second hole current collectors 418 are electrically connected to the second hole electrodes 416 through the via holes H.

The second solar cell 410 may have a textured surface of the second semiconductor substrate 412 in the same manner as the first solar cell 310. The second solar cell 410 further includes a plurality of back surface field layer 426 and a plurality of expositing portions 428.

As shown in FIGS. 5 and 6, a structure of the first solar cell 310 and a structure of the second solar cell 410 have at least one difference. One difference between the structure of the first solar cell 310 and structure of the second solar cell 410 is the different conductivity type of the respective semiconductor substrates.

In embodiments of the invention, the at least one difference in the structure of the first solar cell 310 and the structure of second solar cell 410 includes reference to having semiconductor substrates that are differently doped, such as different doping elements and/or different doping concentrations; that are differently processed; and/or having different surface characteristics, such as texturing or lack thereof. Further, the at least one difference also includes reference to having semiconductor substrates with different crystallinity of silicon, such as single crystal silicon, polycrystalline silicon, or amorphous silicon.

Additionally, the at least one difference also includes reference to having emitter layers of different doped species; electron electrodes of different shapes, characteristics and/or materials; electron current collectors of different shapes, characteristics and/or materials; having or not having anti-reflection layers or a having anti-reflection layers of different shapes, characteristics, materials, layers and/or thicknesses; hole electrodes of different shapes, characteristics and/or materials; hole current collectors of different shapes, characteristics and/or materials; back surface fields of different shapes, characteristics and/or materials; interconnectors of different shape, characteristics and/or materials, and/or arrangements thereof; as well as other differences.

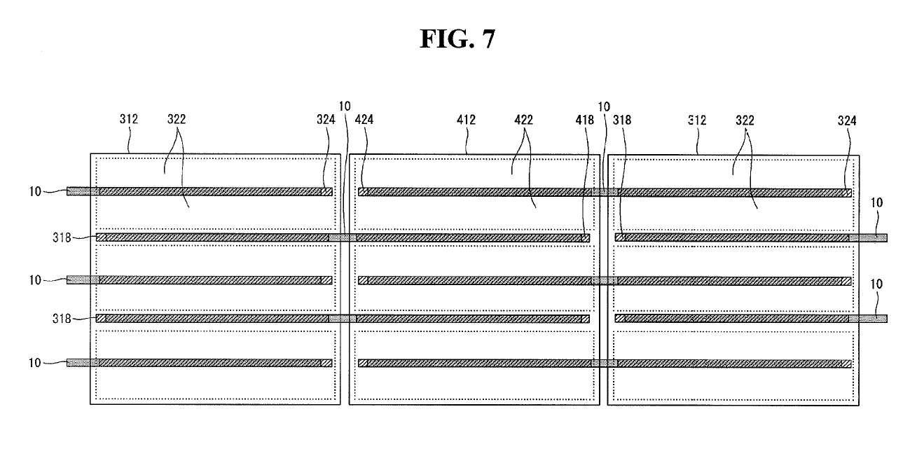

FIG. 7 is a bottom plane view illustrating an arrangement structure and an electrical connection structure of the first and second solar cells.

In the embodiment of the invention, at least one first solar cell 310 and at least one second solar cell 410 are arranged adjacently to each other in a matrix structure. Preferably, but not necessarily, the first solar cells 310 and the second solar cells 410 may be alternately arranged.

Further, the first solar cell 310 is configured so that the first electron electrodes 316 are positioned toward a light source, and the second solar cell 410 is configured so that the second hole electrodes 416 are positioned toward the light source. Accordingly, the first electron current collectors 318, the first hole electrodes 322, and the first hole current collectors 324 of the first solar cell 310 and the second hole current collectors 418, the second electron electrodes 422, and the second electron current collectors 424 of the second solar cell 410 are positioned on the same plane (or the same plane level or may be coplanar).

When the first solar cells 310 and the second solar cells 410 are arranged in the matrix structure, the first solar cells 310 and the second solar cells 410 are arranged so that a longitudinal direction of the first electron current collectors 318 is equal to a longitudinal direction of the second hole current collectors 418, and at the same time, a longitudinal direction of the first hole current collectors 324 is equal to a longitudinal direction of the second electron current collectors 424. Hence, one end of each first electron current collector 318 is opposite to one end of each second hole current collector 418, and one end of each first hole current collector 324 is opposite to one end of each second electron current collector 424.

Accordingly, in the solar cells having the above-described matrix structure, as shown in FIG. 7, an interconnector 10 for electrically connecting the first electron current collectors 318 of the first solar cell 310 to the second hole current collectors 418 of the second solar cell 410 may be straightly positioned on the same plane (or the same plane level). The interconnector 10 for electrically connecting the second electron current collectors 424 of the second solar cell 410 to the first hole current collectors 324 of the first solar cell 310 may be straightly positioned on the same plane (or the same plane level).

In other words, in a solar cell module including the first and second solar cells 310 and 410 according to the embodiment of the invention, the first electron current collectors 318 of the first solar cell 310 and the second hole current collectors 418 of the second solar cell 410 are straightly positioned on the same plane (or the same plane level or may be coplanar), and the first hole current collectors 324 of the first solar cell 310 and the second electron current collectors 424 of the second solar cell 410 are straightly positioned on the same plane (or the same plane level or may be coplanar). Therefore, the electrical connection between the solar cells 310 and 410 using the interconnector 10 can be easily performed. Further, a yield in a module process of the solar cells 310 and 410 can be improved.

In FIG. 7, the interconnector 10, the first electron current collector 318 of the first solar cell 310, and the second hole current collector 418 of the second solar cell 410 are connected in a straight line. In other words, the interconnector 10, the first electron current collector 318, and the second hole current collector 418 are collinear.

In another embodiment of the invention, a textured surface of the interconnector 10 positioned on the back surfaces of the first and second solar cells 310 and 410 may be a surface opposite a surface of the interconnector 10 contacting the back surfaces of the first and second solar cells 310 and 410 in the same manner as the first and second solar cells 110 and 210.

The scope of the invention includes using different solar cells in a module, such as using at least two different solar cells selected from the solar cells shown in FIGS. 2, 3, 5 and 6.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell module, comprising:
at least one first solar cell, the at least one first solar cell including a first semiconductor substrate of a first conductive type, and a first electron current collector and a first hole current collector that are positioned on one surface of the first semiconductor substrate; and
at least one second solar cell, the at least one second solar cell including a second semiconductor substrate of a second conductive type opposite the first conductive type, and a second electron current collector and a second hole current collector that are positioned on one surface of the second semiconductor substrate.

2. The solar cell module of claim 1, wherein the at least one first solar cell and the at least one second solar cell are positioned adjacently to each other.

3. The solar cell module of claim 1, wherein the at least one first solar cell and the at least one second solar cell are alternately positioned.

4. The solar cell module of claim 1, wherein the first electron current collector and the second hole current collector are positioned on the same plane level, and the first hole current collector and the second electron current collector are positioned on the same plane level.

5. The solar cell module of claim 1, wherein the first electron current collector and the second hole current collector are straightly connected to each other using an interconnector.

6. The solar cell module of claim 5, wherein the interconnector has a textured surface formed at a surface opposite a surface of the interconnector contacting the first electron current collector and the second hole current collector.

7. The solar cell module of claim 1, wherein the first electron current collector and the first hole current collector are positioned on a surface opposite a light receiving surface of the first semiconductor substrate, and
the second electron current collector and the second hole current collector are positioned on a surface opposite a light receiving surface of the second semiconductor substrate.

8. The solar cell module of claim 1, wherein the first electron current collector and the second hole current collector are positioned on a straight line, and the first hole current collector and the second electron current collector are positioned on a straight line.

9. The solar cell module of claim 1, further comprising:
upper and lower protective layers that are respectively positioned on and under the at least one first solar cell and the at least one second solar cell;
a transparent member positioned on the upper protective layer; and
a back sheet positioned under the lower protective layer.

10. The solar cell module of claim 1, wherein the first conductive type is a p-type,
the at least one first solar cell further includes a plurality of via holes passing through the first semiconductor substrate, an n-type emitter layer positioned at a light receiving surface of the first semiconductor substrate and in the via holes, a first electron electrode positioned on the emitter layer at the light receiving surface of the first semiconductor substrate, and a first hole electrode that is positioned on a surface opposite the light receiving surface of the first semiconductor substrate and is electrically connected to the first hole current collector, and
the first electron current collector is positioned on the surface opposite the light receiving surface and is electrically connected to the first electron electrode through the via holes.

11. The solar cell module of claim 10, wherein the first electron current collector is formed in a direction crossing the first electron electrode, and the via holes are formed at a crossing of the first electron current collector and the first electron electrode.

12. The solar cell module of claim 1, wherein the second conductive type is an n-type,
the at least one second solar cell further includes a plurality of via holes passing through the second semiconductor substrate, a p-type emitter layer positioned at a light receiving surface of the second semiconductor substrate and in the via holes, a second hole electrode positioned on the emitter layer at the light receiving surface of the second semiconductor substrate, and a second electron electrode that is positioned on a surface opposite the light receiving surface of the second semiconductor substrate and is electrically connected to the second electron current collector, and
the second hole current collector is positioned on the surface opposite the light receiving surface and is electrically connected to the second hole electrode through the via holes.

13. The solar cell module of claim 12, wherein the second hole current collector is formed in a direction crossing the second hole electrode, and the via hole are formed at a crossing of the second hole current collector and the second hole electrode.
